(19) United States
(12) Patent Application Publication
(10) Pub. No.: US 2025/0169162 A1
(43) Pub. Date: May 22, 2025

(54) IRRADIATION-RESISTANT GaN HEMT WITH DECOUPLING REVERSE CONDUCTION CAPABILITY AND FABRICATING METHOD THEREOF

(71) Applicant: NANJING UNIVERSITY, Nanjing (CN)

(72) Inventors: Feng ZHOU, Nanjing (CN); Yu RONG, Nanjing (CN); Hai LU, Nanjing (CN); Weizong XU, Nanjing (CN); Dong ZHOU, Nanjing (CN); Fangfang REN, Nanjing (CN)

(73) Assignee: NANJING UNIVERSITY, Nanjing (CN)

(21) Appl. No.: 18/641,350

(22) Filed: Apr. 20, 2024

(30) Foreign Application Priority Data
Nov. 20, 2023 (CN) 202311541154.7

(51) Int. Cl. H01L 27/06; H01L 29/20; H01L 29/66; H01L 29/778; H01L 29/872

(52) U.S. Cl. CPC H10D 84/811; H10D 8/051; H10D 8/60; H10D 30/015; H10D 30/475; H10D 62/8503

(57) ABSTRACT

The present invention discloses an irradiation-resistant GaN HEMT with decoupling reverse conduction capability and a fabricating method thereof. First gate region metal and second gate region metal are sectionally distributed on a p-type gallium nitride layer in a gate region of the transistor, where the first gate region metal consists of first Schottky metal layers and second ohmic metal layers, and the second gate region metal only consists of a second Schottky metal layer; dielectric layers are filled between the first gate region metal and the second gate region metal, an interconnection metal layer is arranged above the first gate region metal and is connected to an interconnection metal layer above a source to form a reverse freewheeling diode; and gate metal layers are arranged above the second gate region metal and are used as a real gate of the transistor.

### CROSS-REFERENCE TO RELATED APPLICATIONS

The application claims priority to Chinese patent application No. 202311541154.7, filed on Nov. 20, 2023, the entire contents of which are incorporated herein by reference.

### TECHNICAL FIELD

The present invention relates to an irradiation-resistant GaN HEMT with decoupling reverse conduction capability and a fabricating method thereof, and belongs to the technical field of semiconductors.

### BACKGROUND

In recent years, gallium nitride power devices have great potential in many power electronic systems such as aerospace, mobile phone fast charging, data centers, and smart grids due to its superior performance such as high breakdown voltage, low conduction resistance, and fast switching capability. To ensure the safe and reliable operation of aerospace power systems, switching devices therein shall be enhanced (normally off). Currently, most of mainstream commercial gallium nitride high electron mobility transistors use p-type gallium nitride gate cap layer device structures. In practical switch applications, such as bidirectional DC/DC converters, semiconductor power devices need to have reverse current conduction (third quadrant working) capability to safely discharge impact energy from source to drain, especially in the irradiation environment of aerospace. However, due to lack of built-in body diodes, an enhanced gallium nitride high electron mobility transistor can only depend on thinner two-dimensional electron gas conducting channels for third quadrant reverse current conduction, while a working state of the conducting channels is controlled by a gate of the device. Therefore, reverse conduction capability of the device is greatly affected by coupling of the gate of the device.

An existing gallium nitride high electron mobility transistor is shown in FIG. 1. When the transistor performs reverse current conduction, reverse conduction capability is affected by the coupling of the gate of the device, and reverse turn-on voltage depends on the threshold voltage of the device. When the threshold voltage of the device is high, the reverse turn-on voltage also increases, resulting in great reverse turn-on loss; at the same time, to prevent the transistor from being conducted by mistake, the transistor is generally set to be turned off under negative gate voltage, which will also cause an increase in the reverse turn-on voltage and an increase in reverse conduction loss.

Therefore, for technical development of the enhanced gallium nitride high electron mobility transistor in the field of aerospace irradiation, it is urgent to reduce the reverse turn-on voltage and the conduction loss of this type of device, so that the reverse conduction capability of the device is not controlled by the gate of the device, and power application capability and reliability of the device are improved.

### SUMMARY

The present invention aims to provide an irradiation-resistant GaN HEMT with decoupling reverse conduction capability and a fabricating method thereof, for overcoming the defects of the aforementioned technology. A built-in reverse freewheeling diode is formed by connecting a portion of a gate to a source, source current flows to a drain through ohmic metal layers in a gate region during reverse conduction, and therefore, a transistor is not controlled by gate voltage in the reverse working state, thereby achieving decoupling of the reverse turn-on voltage and forward threshold voltage, and reducing reverse conduction loss. Furthermore, a design of using Schottky metal at two ends effectively prevents diffusion of the source current towards the gate through the ohmic metal layers in the gate region along a p-type gallium nitride layer, thereby reducing gate leakage current, and preventing gate and source of a device from punching through under negative gate voltage. The transistor has forward conduction capability and reverse conduction capability at the same time. A preparation method is simple, area of the transistor is not enlarged, and a solution for improving the reverse conduction capability of an enhanced gallium nitride high electron mobility transistor is provided.

In order to solve the above technical problems, the present invention adopts the following technical solution:
an irradiation-resistant GaN HEMT with decoupling reverse conduction capability includes a substrate layer, a gallium nitride layer, and a barrier layer which are successively arranged from bottom to top, where a strip-shaped p-type gallium nitride layer is arranged on the barrier layer, and a Schottky metal layer and gate metal layers are successively arranged above the p-type gallium nitride layer; first ohmic metal layers having different distances to the p-type gallium nitride layer are arranged on two sides of the p-type gallium nitride layer on the barrier layer, where the first ohmic metal layer closer to the p-type gallium nitride layer is called source of the transistor, and the further is called drain; an interconnection metal layer is arranged above the source and the drain, respectively; dielectric layers are filled between the p-type gallium nitride layer, the source and the drain;
first gate region metal and second gate region metal are sectionally distributed on the p-type gallium nitride layer in the gate region of the transistor, where the first gate region metal consists of first Schottky metal layers and second ohmic metal layers, the second gate region metal only consists of a second Schottky metal layer, and the first Schottky metal layers and the second Schottky metal layer form the Schottky metal layer; dielectric layers are filled between the first gate region metal and the second gate region metal, an interconnection metal layer is arranged above the first gate region metal and is connected to an interconnection metal layer above the source (that is, the interconnection metal layer above the first gate region metal is connected to the interconnection metal layer above the source), to form the reverse freewheeling diode; and the gate metal layers are arranged above the second gate region metal and are used as a real gate of the transistor.

The GaN HEMT in the present application is a gallium nitride high electron mobility transistor.

The irradiation-resistant GaN HEMT with decoupling reverse conduction capability effectively solves the problems in the prior art that the gallium nitride high electron mobility transistor has high reverse turn-on voltage and great reverse conduction loss, and the reverse working state is controlled by gate voltage.

If an external Schottky diode and the transistor are integrated into the same chip, additional integration of the Schottky diode will enlarge area of the chip, affect electrical performance of the transistor, and is not conducive to commercial applications; however, through a design of a special structure in the present application, the built-in reverse freewheeling diode is formed through connection of the first gate region metal to the source, so that decoupling of the reverse conduction voltage and the forward threshold voltage is achieved, the reverse turn-on voltage of the transistor is reduced, and the reverse conduction loss is reduced; and through a design of adopting Schottky metal at two ends, gate leakage is effectively reduced, the occurrence that gate and source current of the device (GaN HEMT) punches through under negative gate voltage can be prevented, and the transistor has forward conduction capability and reverse conduction capability at the same time.

For the irradiation-resistant GaN HEMT with decoupling reverse conduction capability, in the first gate region metal, the lower bottom surfaces of the second ohmic metal layers are in direct contact with the p-type gallium nitride layer; and when the irradiation-resistant GaN HEMT with decoupling reverse conduction capability is in reverse conduction, because the source is connected to the second ohmic metal layers in the first gate region metal through the interconnection metal layer, reverse current can flow to the drain from a conducting channel below the second ohmic metal layers without overcoming a reverse biased electric field of a Schottky junction, reverse conduction is not controlled by the forward threshold voltage of the gate, and therefore, decoupling of the reverse conduction voltage and the forward threshold voltage is achieved.

For the irradiation-resistant GaN HEMT with decoupling reverse conduction capability, the gate metal layers on all the second gate region metal are connected together, that is, all the second gate region metal is connected through the gate metal layers, to form the real gate of the transistor; when the irradiation-resistant GaN HEMT with decoupling reverse conduction capability is in forward conduction, because voltage applied by the gate is higher than threshold voltage, enhanced operation is achieved by utilizing two-dimensional electron gas in a channel below the gate to conduct the current; and in addition, because the p-type gallium nitride layer is continuously present in the entire gate region, a gate heterojunction consisting of the second Schottky metal layer, the p-type gallium nitride layer, the barrier layer, and the gallium nitride layer in the gate effectively blocks forward or reverse gate leakage current, and therefore, the device has normal enhanced operation capability.

The first gate region metal and the second gate region metal on the p-type gallium nitride layer are in sectional and alternative arrangement, with p+q sections in total, where the first gate region metal includes p sections, the second gate region metal includes q sections, q−1≤p≤q+1, and p and q are both positive integers.

The first gate region metal can adopt a fully wrapped structure or a non-fully wrapped structure, the fully wrapped structure means that peripheries of the second ohmic metal layers in the first gate region metal are fully wrapped by the first Schottky metal layers, while the non-fully wrapped structure means the peripheries of the second ohmic metal layers in the first gate region metal are not fully wrapped by the first Schottky metal layers.

As one of specific implementations, when the first gate region metal adopts the non-fully wrapped structure, the same section of the first gate region metal is formed by alternative and tight (gap-free) arrangement of the first Schottky metal layers and the second ohmic metal layers which are longitudinally arranged, and two ends of the same section of the first gate region metal must be the first Schottky metal layers; and when the transistor is in reverse conduction, a Schottky barrier formed by the first Schottky metal layers at the two ends of the first gate region metal restrains diffusion of the source current towards the second gate region metal (a real gate of the transistor) through the second ohmic metal layers along the p-type gallium nitride layer, thereby effectively preventing gate and source current of the device from punching through under negative gate voltage.

The first Schottky metal layers and the second ohmic metal layers are in alternative arrangement and tight contact, that is, the first Schottky metal layers and the second ohmic metal layers are in gap-free arrangement in the same section of the first gate region metal. Cross sections of the first Schottky metal layers and the second ohmic metal layers can adopt a structure of a strip shape (such as a rectangle, or a strip shape with irregular edges).

The same (or single) section of the first gate region metal is one section of p sections of the first gate region metal. The same (or single) section of the second gate region metal is one section of q sections of the second gate region metal.

Materials used for the first Schottky metal layers and the second Schottky metal layer in the present application are the same. The description of the “first Schottky metal layers” in the present application is only for convenience of understanding, as the first Schottky metal layers here are interphase or wrapped around the second ohmic metal layers.

Materials used for the first ohmic metal layers and the second ohmic metal layers in the present application are different. The description of “the first ohmic metal layers” and “the second ohmic metal layers” is used because either the first ohmic metal layers or the second ohmic metal layers form ohmic contact with an underlying material.

In the same section of the first gate region metal, the number m of the first Schottky metal layers and the number n of the second ohmic metal layers meet the following relationship: m=n+1, where m and n are both positive integers;
a direction from the source to the drain is a length direction (an x direction), a width direction (a y direction) is mutually perpendicular to the length direction, the Schottky metal layer is sectioned in the width direction and forms the first gate region metal and the second gate region metal, and the first Schottky metal layers and the second ohmic metal layers in the same section of the first gate region metal are in alternative and tight arrangement in the width direction;
as one of preferred specific implementations, the first Schottky metal layers and the second ohmic metal layers both adopt a cube structure, in the same section of the first gate region metal, a width (in the y direction) of each of the first Schottky metal layers located at two ends is a₀, a width of each first Schottky metal layer located in a middle is aₓ, and a subscript x represents the number of the first Schottky metal layers located in the middle; a width of each second ohmic metal layer is by, a subscript y represents the number of the second ohmic metal layers, where a₁>2 μm, a₂≥0 μm, b≥1 μm, 1≤x≤m−2, 1≤y≤n; a length of each of the second ohmic metal layers is equal to that of the first Schottky metal layers, and a ratio of area occupied by the second ohmic metal layers to that occupied by the first Schottky metal layers is

$$\frac{{\sum }_{y = 1}^{n} {b}_{y}}{2 \cdot {a}_{0} + {\sum }_{x = 1}^{m - 2} {a}_{x}} ∈ [ \frac{1}{2} , 2 ] ;$$

a width of a single section of the first gate region metal is w₁,

$${w}_{1} = 2 \cdot {a}_{0} + {\sum }_{x = 1}^{m - 2} {a}_{x} + {\sum }_{y = 1}^{n} {b}_{y}$$

and 10 μm≤w₁≤1000 μm;
the first gate region metal and the second gate region metal are in alternative arrangement in the width direction, and both adopt the cube structure; a width of a single section of the second gate region metal is w₂, a gap between the first gate region metal and the second gate region metal which are adjacent is d, where 10 μm≤w₂≤1000 μm, 2 μm≤d≤10 μm, a ratio of total area of the first gate region metal to that of the second gate region metal is

$$\frac{p \cdot {w}_{1}}{q \cdot {w}_{2}} ∈ [ \frac{1}{2} , 2 ] ,$$

and a width of the entire transistor is w=p·w+q·w₂+(p+q−1)·d. The gap in the present application refers to the minimum distance between the first gate region metal and the second gate region metal.

As another specific implementation, the first gate region metal adopts the fully wrapped structure, the same section of the first gate region metal consists of the first Schottky metal layers and the second ohmic metal layers which are longitudinally arranged, where the first Schottky metal layers tightly wrap the peripheries of the second ohmic metal layers; when the transistor is in reverse conduction, the Schottky junction formed by the first gate region metal can effectively prevent diffusion of the source current towards the real gate of the transistor through the second ohmic metal layers along the p-type gallium nitride layer;
in the width direction (the y direction), the minimum thickness of the first Schottky metal layers wrapping the peripheries of the second ohmic metal layers (that is, the minimum thickness of the edges of the second ohmic metal layers to the edges of the first Schottky metal layers) is a₀, a₀≥2 μm, and a ratio of the area of the second ohmic metal layers to that of the first Schottky metal layers is

$$\frac{1}{2} \sim 2 ;$$

the first gate region metal and the second gate region metal are in alternative arrangement in the width direction; and a width of a single section of the first gate region metal is w₁, a width of the same section of the second gate region metal is w₂, a gap between the first gate region metal and the second gate region metal which are adjacent is d, where 10 μm≤w₁≤1000 μm, 10 μm≤w₂≤1000 μm 2 μm≤d≤10 μm, and a ratio of area of the first gate region metal to that of the second gate region metal is

$$\frac{1}{2} \sim 2.$$

For the convenience of preparation and control, the cross sections of the second ohmic metal layers in this solution are preferred to be a strip, circle, ellipse, or polygon shape.

The first Schottky metal layers tightly wrap the peripheries of the second ohmic metal layers, that is, side walls of the second ohmic metal layers are fully wrapped with the first Schottky metal layers, and the first Schottky metal layers and the second ohmic metal layers are in gap-free arrangement.

In order to further reduce gate leakage, a length of the p-type gallium nitride layer (the direction from the source to the drain is the length direction, that is, the x direction, which is perpendicular to the width direction) is l₁, the first gate region metal and the second gate region metal are equal in a length l₂, and an overlapping length (a length of an overlapping part of the interconnection metal layer and the first gate region metal) of the interconnection metal layer and the first gate region metal is l₃, where l₁≥l₂≥l₃; and it can avoid problems that in a device preparation process, if metal is in direct contact with a barrier layer, gate leakage current will be larger, and in severe cases, source metal can cross the gate to directly conduct with the drain, greatly affecting forward characteristics of enhanced devices.

As one of preferred specific implementations, a gap between the first ohmic metal layers at the source and the p-type gallium nitride layer is 1-3 μm, and a gap between the first ohmic metal layers at the drain and the p-type gallium nitride layer is 4-20 μm.

The above dielectric layer is a single-layer dielectric layer formed by one of materials such as silicon dioxide, silicon nitride, or aluminum trioxide, or a multi-layer dielectric layer formed by multiple materials above.

As one of specific implementations, the first ohmic metal layers at the source and the drain adopt a structure of Ti/Al (0.12 μm-0.68 μm); the second ohmic metal layers in the first gate region metal adopt a structure of Ni/Pt/Al (0.12 μm-0.86 μm); and the Schottky metal layers in the first gate region metal and the second gate region metal adopt a structure of TiN/Al (0.12 μm-0.76 μm).

An innovative structure of the present invention is mainly represented in the gate of the transistor: the first gate region metal and the second gate region metal are sectionally arranged above the p-type gallium nitride layer, and the dielectric layers are filled in a middle gap region, where the first gate region metal includes the first Schottky metal layers and the second ohmic metal layers, on which the interconnection metal layer is arranged and connected to the source to form the reverse freewheeling diode; and the second gate region metal only consists of the second Schottky metal layer, on which the gate metal layers are arranged as the real gate of the transistor. Through the reverse freewheeling diode built in the transistor, bidirectional conduction capability of a first quadrant and a third quadrant is achieved, so that energy impact from the source to the drain can be safely discharged under a situation that forward characteristics are not affected; besides, decoupling of the reverse conduction voltage and the forward threshold voltage is achieved through arrangement of the ohmic metal layers in the first gate region metal, reverse conduction is not controlled by the Schottky junction, the reverse turn-on voltage of the transistor is reduced, and the reverse conduction loss is reduced; and the Schottky metal layers at the two ends of the first gate region metal effectively prevent gate and source current from punching through via the p-type gallium nitride layer during reverse conduction. Therefore, the transistor with bidirectional conduction has capability of high forward threshold voltage and low reverse threshold voltage at the same time, a preparation method is simple, and the area of the transistor is not enlarged.

A fabricating method of an irradiation-resistant GaN HEMT with decoupling reverse conduction capability includes the following steps:
1) enabling an epitaxial wafer to successively include a substrate layer, a gallium nitride layer, a barrier layer, and a p-type gallium nitride layer from bottom to top, and removing the p-type gallium nitride layer in the non-graphic region by using an inductively coupled plasma dry etching method, so that only the gate region retains the p-type gallium nitride layer;
2) enabling dielectric layers to grow on the entire epitaxial wafer by using a plasma enhanced chemical vapor deposition method; in the source region and drain region, etching the dielectric layers and the barrier layer and depositing first ohmic metal layers by using the inductively coupled plasma dry etching method and a photolithography stripping method; subsequently, at the first gate region metal, etching the dielectric layers and depositing the second ohmic metal layers; at the first gate region metal and second gate region metal, etching the dielectric layers and depositing the Schottky metal layer;
3) enabling the dielectric layers to grow on the entire epitaxial wafer by using the plasma enhanced chemical vapor deposition method again; subsequently, removing the dielectric layer above the second gate region metal to form deposition holes by using the inductively coupled plasma dry etching method; and depositing the gate metal layers above the metal layer from which the dielectric layers are removed by using the photolithography stripping method;
4) removing the dielectric layers above the first gate region metal, the source and the drain to form deposition holes by using the inductively coupled plasma dry etching method; and depositing the interconnection metal layers above the metal layer from which the dielectric layers are removed by using the photolithography stripping method; and
5) finally, covering the entire epitaxial wafer with a passivation layer, and thickening the metal layer in bonding pad regions of the source, the drain, and the gate of the transistor to complete preparation of the transistor.

When etching damage is caused, a following method is used to repair the etching damage: placing the epitaxial wafer in a solution of tetramethylammonium hydroxide (TMAH), or treating the epitaxial wafer with oxygen plasma combined with a diluted hydrochloric acid solution.

In the above step 2), a thickness of each dielectric layer is 10 nm-100 nm.

In the above step 3), the thickness of each dielectric layer is 1000 nm-5000 nm.

The photolithography stripping method used in the above steps 2), 3) and 4) includes: firstly enabling the non-graphic region to be covered with photoresist and exposuring, then enabling the entire epitaxial wafer to be covered with a metal layer, removing the metal layer from the non-graphic region by a striping method, and finally enabling the metal layer to leave in a graphic region.

Inductively coupled plasma dry etching (ICP etching) conditions include: etching gas is Cl₂, Ar and BCl₃, pressure of a reaction chamber is controlled between 0.6 Pa-1.2 Pa, etching power is 200 W-300 W, and direct current bias is minus 60 V-100 V.

Materials for the passivation layer in the step 5) are any one or combination of two or more of silicon dioxide, silicon nitride, or polyimide, with a thickness of 1000 nm-4000 nm.

As routine operation, before completing preparation of the transistor, steps further include depositing a PAD thickened metal layer, slicing the transistor, and packaging the transistor.

The above device can be used in power electronic systems.

Techniques not mentioned in the present invention all refer to the prior art.

According to the irradiation-resistant GaN HEMT with decoupling reverse conduction capability disclosed by the present invention, the reverse turn-on voltage and the forward threshold voltage of the transistor are decoupled, so that the reverse turn-on voltage of the transistor is reduced, reverse conduction loss is reduced, the transistor is not controlled by a gate voltage in a reverse working state, it is ensured that the transistor has normal forward conduction capability and normal reverse conduction capability at the same time, gate leakage current is reduced, the preparation method is simple, the area of the transistor is not enlarged, high integration level and small volume are achieved, and a solution for improving the reverse conduction capability of the enhanced gallium nitride high electron mobility transistors is provided.

### BRIEF DESCRIPTION OF DRAWINGS

FIG. 1 shows a structural schematic diagram of a gallium nitride high electron mobility transistor in the prior art;

FIG. 2 shows a structural schematic diagram of an irradiation-resistant GaN HEMT with decoupling reverse conduction capability, having extremely high gate to source current leakage;

FIG. 3 shows a structural schematic diagram (showing a part of gate metal layers) of the irradiation-resistant GaN HEMT with decoupling reverse conduction capability according to the present invention;

FIG. 4 shows a schematic diagram of a fabricating process of the irradiation-resistant GaN HEMT with decoupling reverse conduction capability in embodiment 1 of technical solutions of the present invention (showing a part of gate metal layers; a shows etching a p-type gallium nitride layer; b shows enabling a first dielectric layer to grow, and etching and depositing an ohmic metal layer and a Schottky metal layer; c shows enabling a second dielectric layer to grow, and etching and depositing gate metal layers; d shows etching and depositing interconnection metal layers);

FIG. 5 shows a schematic diagram of a fabricating process of the irradiation-resistant GaN HEMT with decoupling reverse conduction capability in embodiment 2 of technical solutions of the present invention (showing a part of gate metal layers; a shows etching a p-type gallium nitride layer; b shows enabling a first dielectric layer to grow, and etching and depositing an ohmic metal layer and a Schottky metal layer; c shows enabling a second dielectric layer to grow, and etching and depositing gate metal layers; d shows etching and depositing interconnection metal layers); and

FIG. 6 shows a structural schematic diagram (showing all gate metal layers) of the irradiation-resistant GaN HEMT with decoupling reverse conduction capability according to the present invention.

In figures: 1—substrate layer, 2—gallium nitride layer, 3—barrier layer, 4—p-type gallium nitride layer, 5—dielectric layer, 6—ohmic metal layer, 61—first ohmic metal layer, 62—second ohmic metal layer, 7—Schottky metal layer, 71—first Schottky metal layer, 72—second Schottky metal layer, 8—gate metal layer, 9—interconnection metal layer.

### DETAILED DESCRIPTION OF THE EMBODIMENTS

In order to better understand the present invention, the content of the present invention will be further elucidated in conjunction with embodiments, but the content of the present invention is not limited to the following embodiments.

Relative orientations or positional relationships indicated by terms: up and down, left and right, top, bottom, horizontal, vertical, width, length, etc. in the present application are based on those shown in the accompanying drawings, intended only for the convenience of describing the present application, and not intended to indicate or imply that the referred apparatus or element must be provided with a particular orientation or constructed and operated with a particular orientation, therefore not allowed to be construed as an absolute limitation of the present application.

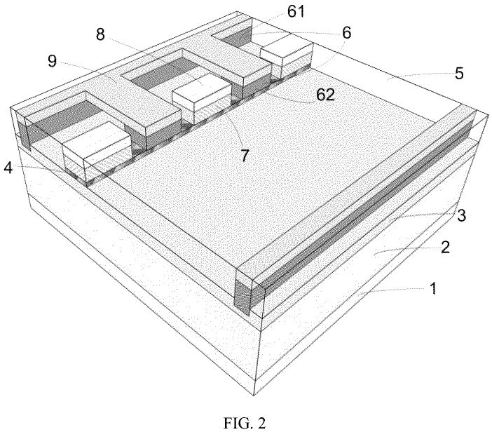

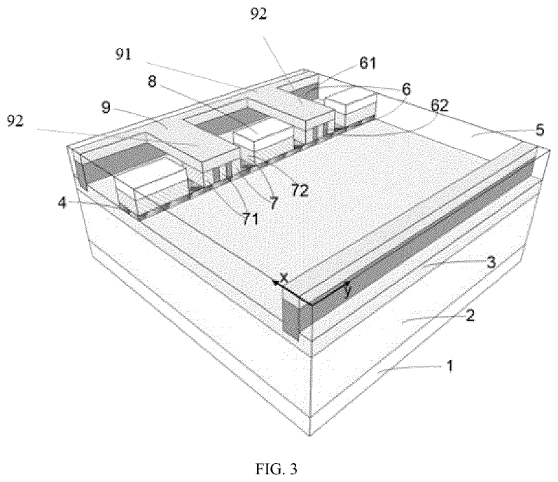

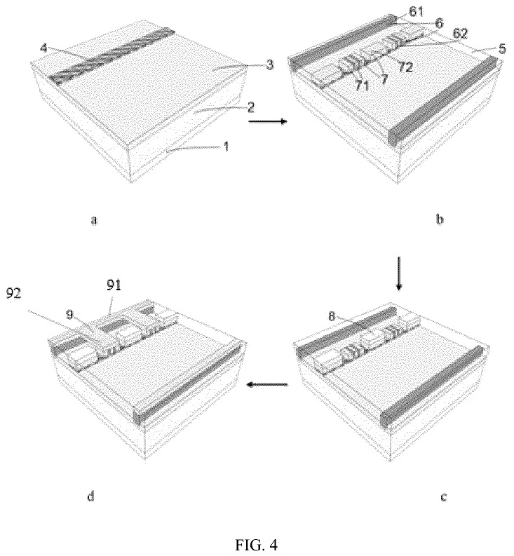

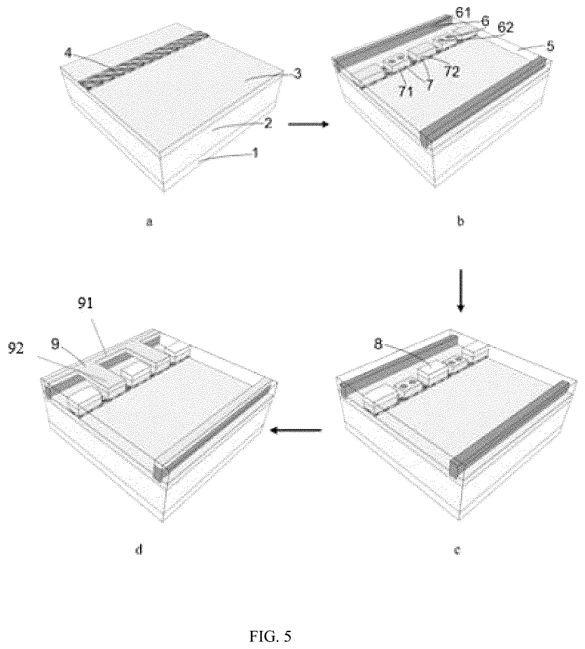

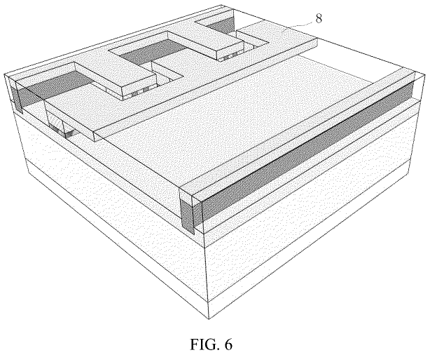

Note: In order to visually see specific structures of first gate region metal 71 and second gate region metal 72, only a part of gate metal layers 8 is shown in FIG. 2, FIG. 3, FIG. 4, and FIG. 5, while FIG. 6 shows all the gate metal layers 8.

### Embodiment 1

As shown in FIG. 3, an irradiation-resistant GaN HEMT with decoupling reverse conduction capability includes a substrate layer 1, a gallium nitride layer 2, and a barrier layer 3 which are successively arranged from bottom to top, where a strip-shaped p-type gallium nitride layer 4 is arranged on the barrier layer 3, and a Schottky metal layer 7 and gate metal layers 8 are successively arranged above the p-type gallium nitride layer 4; first ohmic metal layers 61 having different distances to the p-type gallium nitride layer 4 are arranged on two sides of the p-type gallium nitride layer 4 on the barrier layer 3, where the first ohmic metal layer 61 closer to the p-type gallium nitride layer 4 is called the source of a transistor, and the further is called the drain; an interconnection metal layer 9 is arranged above the source and the drain, respectively; dielectric layers 5 are filled between the p-type gallium nitride layer 4, the source and the drain;

first gate region metal and second gate region metal are sectionally distributed above the p-type gallium nitride layer 4 in a gate region of the transistor, and the dielectric layers 5 are filled in a middle gap region between the first gate region metal and the second gate region metal which are adjacent, where a single section of the first gate region metal consists of first Schottky metal layers 71 and second ohmic metal layers 62, an interconnection metal layer 9 is arranged above the first gate region metal, the interconnection metal layer 9 above the first gate region metal is connected to an interconnection metal layer 9 above the source to form a reverse freewheeling diode; the second gate region metal only consists of a second Schottky metal layer 72, the gate metal layers 8 are arranged above the second gate region metal, and the gate metal layers 8 above all the second gate region metal are connected together to form a real gate of the transistor, as shown in FIG. 6; and the first Schottky metal layers 71 and the second Schottky metal layer 72 form the Schottky metal layer.

As shown in FIG. 3, the first gate region metal and the second gate region metal are alternatively arranged, the number p of the first gate region metal is set as 2 sections, and the number q of the second gate region metal is set as 3 sections.

A non-fully wrapped structure of a single section of the first gate region metal is formed by alternative arrangement and tight contact of the first Schottky metal layers 71 and the second ohmic metal layers 62 which are longitudinally arranged, and two ends of the single section of the first gate region metal must be the first Schottky metal layers 71, as shown in FIG. 3, the first Schottky metal layers 71 and the second ohmic metal layers 62 both adopt a cube structure, the number m of the first Schottky metal layers 71 is set as 3, and the number n of the second ohmic metal layers 62 is set as 2; a width (in a y direction in FIG. 3) of each of the first Schottky metal layers 71 at the two ends is a₀=4 μm, and a width of each of the first Schottky metal layers 71 located in a middle is a₁=5 μm; a width of each second ohmic metal layer 62 meets b₁=b₂=3.5 μm; in the part of the first gate region metal, a length of each of the second ohmic metal layers 62 is equal to that of the first Schottky metal layers 71, and a ratio of area occupied by the second ohmic metal layers to that occupied by the first Schottky metal layers is

$$\frac{7}{13} ;$$

and a width w₁ of the single section of the first gate region metal is 20 μm, and two sections of the first gate region metal 71 have the same structure, magnitude and parameters.

A width w₂ of the single section of the second gate region metal is 20 μm, a gap d between the first gate region metal and the second gate region metal which are adjacent is 5 μm, a ratio of total area of the first gate region metal to that of the second gate region metal is

$$\frac{2}{3} ,$$

and a width w of the entire transistor is 120 μm. Three sections of the second gate region metal have the same structure, magnitude and parameters.

Length l₁ (in an x direction in FIG. 3) of the p-type gallium nitride layer 4 is 2 μm, and length l₂ of the first gate region metal and the second gate region metal above the p-type gallium nitride layer is 2 μm (the first gate region metal and the second gate region metal are equal in the length l₂); and length l₃ of an overlapping part of the interconnection metal layer 9 and the first gate region metal is 2 μm. It can be solved that in a device preparation process, metal directly contact with the barrier layer 3 will cause a large gate leakage, and in severe cases, source metal can cross the gate to conduct with the drain, greatly affecting forward characteristics of enhanced devices.

For the irradiation-resistant GaN HEMT with decoupling reverse conduction capability, when the transistor is in reverse conduction, because the second ohmic metal layers 62 in the first gate region metal are connected to the source through the interconnection metal layer 9, reverse current can flow to the drain from a conducting channel below the second ohmic metal layers 62 without overcoming a reverse biased electric field of a Schottky junction, reverse conduction is not controlled by forward threshold voltage of the gate of the device, and decoupling of reverse conduction voltage and the forward threshold voltage is achieved. In addition, a Schottky barrier formed by the first Schottky metal layers 71 at the two ends of the first gate region metal may restrain diffusion of source current towards the second gate region metal (the real gate of the transistor) through the second ohmic metal layers 62 along the p-type gallium nitride layer 4, thereby effectively preventing gate and source current of the device from punching through under negative gate voltage.

For the irradiation-resistant GaN HEMT with decoupling reverse conduction capability, all the second gate region metal is connected together through the gate metal layers 8, to form the real gate of the transistor; when the transistor is in forward conduction, because voltage applied by the gate is higher than threshold voltage, enhanced operation is achieved by utilizing two-dimensional electron gas in a channel below the gate to conduct the current; and in addition, because the p-type gallium nitride layer 4 is continuously present on the entire gate region, a gate heterojunction consisting of the second Schottky metal layer 72, the p-type gallium nitride layer 4, the barrier layer 3 and the gallium nitride layer 2 in the gate effectively blocks forward or reverse gate leakage current.

A fabricating method of the irradiation-resistant GaN HEMT with decoupling reverse conduction capability, as shown in FIG. 4, includes the following steps:

Step 1: as shown in FIG. 4a, etching the p-type gallium nitride layer 4;

enabling an epitaxial wafer to successively include the silicon substrate layer of 0.65 mm, the gallium nitride layer 2 of 4500 nm, the barrier layer 3 of 13 nm, and the p-type gallium nitride layer 4 of 100 nm from bottom to top, and removing the p-type gallium nitride layer 4 in a non-graphic region by using an inductively coupled plasma dry etching method, so that only the gate region retains the p-type gallium nitride layer 4. A method for repairing etching damage includes: placing the epitaxial wafer in a solution of tetramethylammonium hydroxide (TMAH) for treatment.

Step 2: as shown in FIG. 4b, enabling the first dielectric layer 5 to grow, and etching and depositing the ohmic metal layer 6 (including the first ohmic metal layers 61 and the second ohmic metal layers 62) and the Schottky metal layer 7: enabling the silicon dioxide dielectric layer 5 of 50 nm to grow on the entire epitaxial wafer by using the plasma enhanced chemical vapor deposition method; etching the barrier layer 3 in a source region and a drain region at the same time by an inductively coupled plasma dry etching method and a photolithography stripping method, and successively depositing the first ohmic metal layers 61 of which materials are Ti/Al (100 nm/500 nm); then etching the dielectric layer 5 at the first gate region metal, and successively depositing the second ohmic metal layers 62 of which materials are Ni/Pt/Al (150 nm/200 nm/500 nm); and then etching the dielectric layer 5 at the first gate region metal and the second gate region metal, and depositing the Schottky metal layer 7 (including the first Schottky metal layers 71 and the second Schottky metal layer 72) of which materials are TiN/Al (180 nm/500 nm). The aforementioned “at the same time” means that the first ohmic metal layer 61 in the source region and the first ohmic metal layer 61 in the drain region are deposited at the same time, the gap between the first ohmic metal layer 61 at the source and the p-type gallium nitride layer 4 is 2 μm, the gap between the first ohmic metal layer 61 at the drain and the p-type gallium nitride layer 4 is 10 μm, “successively” means that when the second ohmic metal layers 62 are deposited, firstly a nickel metal layer is deposited, then a platinum metal layer is deposited, then an aluminum metal layer is deposited, and meanings of other similar expressions are similar.

The second ohmic metal layers 62 of the gate part and the first Schottky metal layers 71 form the first gate region metal, the second Schottky metal layer 72 forms the second gate region metal, area occupied by a first gate region metal layer section to that occupied by a second gate region metal layer section on the p-type gallium nitride layer 4 is 2:3, and a distance between the first gate region metal layer section and the second gate region metal layer section is 5 μm.

Step 3: as shown in FIG. 4c, enabling the second dielectric layer 5 to grow, and etching and depositing the gate metal layers 8:

enabling the silicon dioxide dielectric layer 5 with a thickness of 4000 nm to grow on the entire epitaxial wafer once again by using the plasma enhanced chemical vapor deposition method; then removing the dielectric layer 5 above the second gate region metal to form deposition holes by using the inductively coupled plasma dry etching method; and by using the photolithography stripping method, successively depositing titanium/aluminum metal with a thickness of 200 nm/5000 nm as the gate metal layers 8 above the metal layer from which the dielectric layers 5 are removed.

Step 4: as shown in FIG. 4d, etching and depositing the interconnection metal layers 9:

removing the dielectric layers 5 above the first gate region metal, the source, a region between the first gate region metal and the source, as well as the drain to form deposition holes by using the inductively coupled plasma dry etching method; and by using photolithography stripping method, successively depositing titanium/aluminum metal with a thickness of 200 nm/4000 nm as the interconnection metal layers 9 above the metal layer from which the dielectric layers 5 are removed.

The photolithography stripping method used in the above steps includes: firstly enabling the non-graphic region to be covered with photoresist, then enabling the entire epitaxial wafer to be covered with a metal layer, removing the metal layer from the non-graphic region by a striping method, and finally enabling the metal layer to leave in a graphic region; and ICP etching conditions include: etching gas is Cl₂, Ar and BCl₃, pressure of a reaction chamber is 1.0 Pa, etching power is 200 W, and direct current bias is minus 100 V.

Step 5: covering a passivation layer, thickening a metal bonding pad, and completing preparation:

finally, covering the entire epitaxial wafer with a silicon dioxide passivation layer with a thickness of 2000 nm, and depositing a PAD thickened aluminum metal layer (3000 nm) in bonding pad regions of the source, the drain, and the gate of the transistor, then performing transistor slicing and transistor packaging, and finally completing preparation of the transistor.

### Embodiment 2

As shown in FIG. 5, an irradiation-resistant GaN HEMT with decoupling reverse conduction capability includes a substrate layer 1, a gallium nitride layer 2, and a barrier layer 3 which are arranged successively from bottom to top, where a strip-shaped p-type gallium nitride layer 4 is arranged on the barrier layer 3, and a Schottky metal layer 7 and gate metal layers 8 are successively arranged above the p-type gallium nitride layer 4; first ohmic metal layers 61 having different distances to the p-type gallium nitride layer 4 are arranged on two sides of the p-type gallium nitride layer 4 on the barrier layer 3, where the first ohmic metal layer closer to the p-type gallium nitride layer 4 is called source of a transistor, and the further is called drain; an interconnection metal layer 9 is arranged above the source and the drain, respectively; in a gate region of the transistor, first gate region metal and second gate region metal are sectionally arranged above the p-type gallium nitride layer 4, and dielectric layers 5 are filled in a middle gap region between two adjacent sections; where the first gate region metal consists of first Schottky metal layers 71 and the second ohmic metal layers 62, seven cylindrical grooves (not drawn in accordance with actual number and sizes in FIG. 5) with a diameter of 1.6 μm are arranged in a single section of the first Schottky metal layers 71, the second ohmic metal layer 62 is filled in each groove (that is, the first Schottky metal layers 71 form a tight fully wrapped structure on the peripheries of the second ohmic metal layers 62, the second ohmic metal layers 62 are cylindrical, and the first Schottky metal layers 71 adopt a cube structure wrapping the cylindrical second ohmic metal layers 62), the interconnection metal layer 9 is arranged above the first gate region metal and is connected to the source to form a reverse freewheeling diode; and the second gate region metal only consists of a second Schottky metal layer 72, and the gate metal layers 8 are arranged above the second gate region metal and are used as a real gate of the transistor.

As shown in FIG. 5, the first gate region metal and the second gate region metal are alternatively arranged, the number p of the first gate region metal is set as 2 sections, and the number q of the second gate region metal is set as 3 sections. In the width direction, the minimum thickness do of the first Schottky metal layers 71 wrapping the peripheries of the second ohmic metal layers 62 is 4 μm, and a ratio of the area of the second ohmic metal layers 62 to that of the first Schottky metal layers 71 is

$$\frac{7}{13} ;$$

a width w₁ of a single section of the first gate region metal is 20 μm, and two sections of the first gate region metal 71 have the same structure, magnitude and parameters;

a width w₂ of a single section of the second gate region metal is 20 μm, a gap d between the first gate region metal 71 and the second gate region metal 72 which are adjacent is 5 μm, a ratio of total area of the first gate region metal to that of the second gate region metal is

$$\frac{2}{3} ,$$

and a width w of the entire transistor is 120 μm. Three sections of the second gate region metal have the same structure, magnitude and parameters.

Lower bottom surfaces of the second ohmic metal layers 62 in a cylindrical groove region are in contact with the p-type gallium nitride layer 4, and outer parts of the second ohmic metal layers 62 are surrounded by the first Schottky metal layers 71. In the embodiment 1, only two sides of the cuboid second ohmic metal layers 62 are wrapped with the first Schottky metal layers 71, so that the second ohmic metal layers 62 adopt a non-fully wrapped structure; while a cylindrical structure is adopted in the embodiment 2, so that the peripheries of the second ohmic metal layers 62 are wrapped, and a fully wrapped structure is formed. When the transistor is in reverse conduction, a Schottky junction formed by the first Schottky metal layers 71 can effectively prevent diffusion of source current towards the real gate (the second gate region metal) of the transistor through the second ohmic metal layers 62 along the p-type gallium nitride layer 4, and therefore, a device in the embodiment 2 is lower in reverse gate leakage current, smaller in reverse turn-on voltage and smaller in reverse conduction loss.

A preparation scheme of the device, and parameters not mentioned in the embodiment 2, etc. all refer to the embodiment 1, and process stages corresponding to FIG. 5a, FIG. 5b, FIG. 5c and FIG. 5d in FIG. 5 are respectively consistent with those corresponding to FIG. 4a, FIG. 4b, FIG. 4c and FIG. 4d in FIG. 4.

### Comparative Embodiment 1

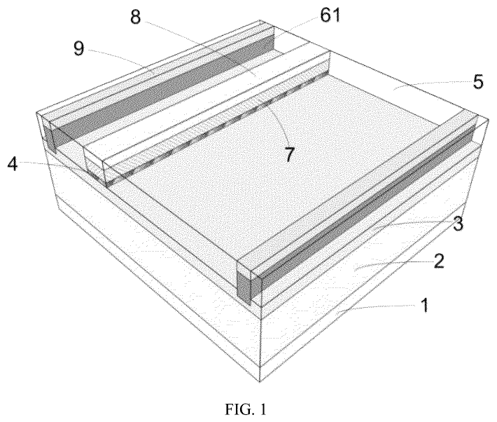

As shown in FIG. 1, a device adopts a structure including a substrate layer 1, a gallium nitride layer 2, and a barrier layer 3 which are successively arranged from bottom to top, where a strip-shaped p-type gallium nitride layer 4 is arranged on the barrier layer 3, and a Schottky metal layer 7 and gate metal layers 8 are successively arranged on the p-type gallium nitride layer 4 from bottom to top; first ohmic metal layers 61 having different distances to the p-type gallium nitride layer 4 are arranged on two sides of the p-type gallium nitride layer 4 on the barrier layer 3, where the first ohmic metal layer closer to the p-type gallium nitride layer 4 is called source, and the further is called drain; an interconnection metal layer 9 is arranged above the source and the drain, respectively; dielectric layers 5 are filled between the p-type gallium nitride layer 4, the source and the drain. A preparation method and parameters refer to the embodiment 1 and existing standards.

### Comparative Embodiment 2

A structure of a device is shown in FIG. 2, a preparation method and parameters refer to the embodiment 1, and the comparative embodiment 2 is different from the embodiment 1 and the embodiment 2 in that the first gate region metal of the device only consists of second ohmic metal layers 62. A gate of the transistor adopts a manner that a Schottky metal layer 7 and the second ohmic metal layers 62 are in sectional and spacing arrangement, where the gate metal layers are arranged on the Schottky metal layer 7 to be used as the real gate of the transistor, interconnection metal layers are arranged on the second ohmic metal layers 62 and connected to the source, decoupling of reverse conduction voltage and forward threshold voltage can be achieved, and the gate metal layers on all the second gate region metal are also connected together. However, an inventor finds that the gate to source leakage current of the device structure is extremely high under negative gate voltage, specifically represented as: when the transistor is in reverse conduction, because the first gate region metal only consists of the second ohmic metal layers 62, source current is extremely easy to diffuse towards the second gate region metal (the real gate of the transistor) through the second ohmic metal layers 62 along the p-type gallium nitride layer 4, and gate and source leakage in this design is extremely high.

Table 1 shows experiment test data of the gallium nitride high electron mobility transistors prepared through technical solutions in the comparative embodiments and the embodiments, including: reverse turn-on voltage, reverse conduction loss, gate leakage current, and whether to be controlled by gate voltage.

TABLE 1

| Devices | Reverse turn- | Reverse | Gate leakage | Whether | |
|---|---|---|---|---|---|
| prepared | on voltage | conduction loss | current (A) | to be | Irradiation- |
| through different | (V) (when | (mJ) (Short | (negative gate | controlled | resistant |
| technical | threshold | circuit diode | voltage is | by gate | burning |
| solutions: | voltage is 3 V) | mode test) | minus 3 V) | voltage | capability |
| Comparative | 3.00 | 750 | 10⁻⁷ | Yes | Extremely |
| embodiment 1 | | | | | weak |
| Comparative | 1.51 | 240 | 10⁻³ | No | Weak |
| embodiment 2 | | | | | |
| Embodiment 1 | 1.50 | 238 | 10⁻⁶ | No | Strong |
| Embodiment 2 | 1.48 | 235 | 10⁻⁷ | No | Strong |

From Table 1, it can be seen that test data in the embodiments of the present invention is significantly better than that in the conventional technology, where the reverse turn-on voltage and the reverse conduction loss are significantly lower than existing technical values, indicating that the technical solution in the examples not only reduces turn-on voltage of the device, but also gets rid of control of the gate voltage, besides, the device has extremely low gate leakage current, a preparation method is simple, area of the transistor is not enlarged, and a solution for improving the reverse conduction capability of the enhanced gallium nitride high electron mobility transistors is provided.

The irradiation-resistant burning capability here is comprehensively obtained by comparing the reverse turn-on voltage and the reverse conduction loss of the devices in the comparative embodiments and the embodiments, the reverse turn-on voltage and the reverse conduction loss in the embodiment 1 and the embodiment 2 are the lowest, indicating that device energy loss caused by irradiation is small, irradiation burning is not liable to occur, the irradiation-resistant burning capability is the strongest, and conclusions that the irradiation-resistant capability in the comparative embodiment 2 is “weak” and the irradiation-resistant capability in the comparative embodiment 1 is “extremely weak” can be successively obtained.

1. An irradiation-resistant GaN HEMT with decoupling reverse conduction capability, comprising a substrate layer, a gallium nitride layer, and a barrier layer which are successively arranged from bottom to top, wherein a strip-shaped p-type gallium nitride layer is arranged on the barrier layer, and a Schottky metal layer and gate metal layers are successively arranged above the p-type gallium nitride layer; first ohmic metal layers having different distances to the p-type gallium nitride layer are arranged on two sides of the p-type gallium nitride layer on the barrier layer, wherein the first ohmic metal layers closer to the p-type gallium nitride layer is a source, and the first ohmic metal layers farther to the p-type gallium nitride layer is a drain; an interconnection metal layer is arranged above the source and the drain, respectively; dielectric layers are filled between the p-type gallium nitride layer, the source and the drain;
first gate region metal and second gate region metal are sectionally distributed on the p-type gallium nitride layer, wherein the first gate region metal consists of first Schottky metal layers and second ohmic metal layers, the second gate region metal only consists of a second Schottky metal layer, and the first Schottky metal layers and the second Schottky metal layer form the Schottky metal layer; the dielectric layers are filled between the first gate region metal and the second gate region metal, a first portion of the interconnection metal layer is arranged above the first gate region metal and is connected to a second portion of the interconnection metal layer above the source to form a reverse freewheeling diode; and the gate metal layers are arranged above the second gate region metal and are used as a real gate of the irradiation-resistant GaN HEMT with decoupling reverse conduction capability.

2. The irradiation-resistant GaN HEMT with decoupling reverse conduction capability according to claim 1, wherein in the first gate region metal, lower bottom surfaces of the second ohmic metal layers are in direct contact with the p-type gallium nitride layer; and when the irradiation-resistant GaN HEMT with decoupling reverse conduction capability is in reverse conduction, the source is connected to the second ohmic metal layers through the interconnection metal layer, reverse current flows to the drain from a conducting channel below the second ohmic metal layers without overcoming a reverse biased electric field of a Schottky junction, reverse conduction is not controlled by forward threshold voltage of the real gate of the irradiation-resistant GaN HEMT, and decoupling of reverse conduction voltage and the forward threshold voltage is achieved.

3. The irradiation-resistant GaN HEMT with decoupling reverse conduction capability according to claim 1, wherein the gate metal layers on all of the second gate region metal are connected together to form the real gate of the irradiation-resistant GaN HEMT; when the irradiation-resistant GaN HEMT with decoupling reverse conduction capability is in forward conduction, because voltage applied by the real gate is higher than a threshold voltage, enhanced operation is achieved by utilizing a two-dimensional electron gas in a channel below the real gate to conduct a drain to source current; and the p-type gallium nitride layer is continuously present in the entire gate region, and a gate heterojunction consisting of the second Schottky metal layer, the p-type gallium nitride layer, the barrier layer and the gallium nitride layer in the real gate effectively blocks forward or reverse gate leakage current.

4. The irradiation-resistant GaN HEMT with decoupling reverse conduction capability according to claim 1, wherein the first gate region metal and the second gate region metal are in alternating arrangement, a number of the first gate region metal is set to be p, a number of the second gate region metal is set to be q, then q−1≤p≤q+1, and p and q are both positive integers; and the first gate region metal adopts a fully wrapped structure or a non-fully wrapped structure, the fully wrapped structure means that the second ohmic metal layers in the first gate region metal are fully wrapped by the first Schottky metal layers, while the non-fully wrapped structure means that the second ohmic metal layers in the first gate region metal are not fully wrapped by the first Schottky metal layers.

5. The irradiation-resistant GaN HEMT with decoupling reverse conduction capability according to claim 4, wherein when the first gate region metal adopts the non-fully wrapped structure, a same section of the first gate region metal is formed by alternating and tight arrangement of the first Schottky metal layers and the second ohmic metal layers which are longitudinally arranged, and two ends of the same section of the first gate region metal must be the first Schottky metal layers; and when the irradiation-resistant GaN HEMT is in reverse conduction, a Schottky barrier formed by the first Schottky metal layers at the two ends of the same section of the first gate region metal restrains diffusion of source current towards the second gate region metal through the second ohmic metal layers along the p-type gallium nitride layer, thereby preventing gate and source current from punching through under negative gate voltage.

6. The irradiation-resistant GaN HEMT with decoupling reverse conduction capability according to claim 5, wherein in the same section of the first gate region metal, a number m of the first Schottky metal layers and a number n of the second ohmic metal layers meet the following relationship: m=n+1, and m and n are both positive integers;
a direction from the source to the drain is a length direction, that is, an x direction, a width direction is a y direction, and the first Schottky metal layers and the second ohmic metal layers in the same section of the first gate region metal are in alternating and tight arrangement in the width direction;
for the first Schottky metal layers in the same section of the first gate region metal, a width of each of the first Schottky metal layers located at two ends is do, a width of each of the first Schottky metal layers located in a middle is aₓ, and a subscript x represents the number of the first Schottky metal layers located in the middle; a width of each of the second ohmic metal layers is by, a subscript y represents the number of the second ohmic metal layers, wherein a₀≥2 μm, aₓ≥0 μm, b_{y}≥1 μm, 1≤x≤m−2, 1≤y≤n, a length of each of the second ohmic metal layers is equal to that of the first Schottky metal layers, and a ratio of area occupied by the second ohmic metal layers to the area occupied by the first Schottky metal layers is
$$\frac{{\sum }_{y = 1}^{n} {b}_{y}}{2 \cdot {a}_{0} + {\sum }_{x = 1}^{m - 2} {a}_{x}} ∈ [ \frac{1}{2} , 2 ] ;$$
a width of a single section of the first gate region metal is w₁,
$${w}_{1} = 2 \cdot {a}_{0} + {\sum }_{x = 1}^{m - 2} {a}_{x} + {\sum }_{y = 1}^{n} {b}_{y}$$
and 10 μm≤w₁≤1000 μm; and
the first gate region metal and the second gate region metal are in alternating arrangement in the width direction; a width of the single section of the second gate region metal is w₂, a gap between the first gate region metal and the second gate region metal which are adjacent is d, wherein 10 μm≤w₂≤1000 μm, 2 μm≤d≤10 μm, a ratio of a total area of the first gate region metal to a total area of the second gate region metal is
$$\frac{p \cdot {w}_{1}}{q \cdot {w}_{2}} ∈ [ \frac{1}{2} , 2 ] ,$$
and a width of the irradiation-resistant GaN HEMT is w=p·w₁+q·w₂+(p+q−1)·d.

7. The irradiation-resistant GaN HEMT with decoupling reverse conduction capability according to claim 4, wherein
when the first gate region metal adopts the fully wrapped structure, a same section of the first gate region metal consists of the first Schottky metal layers and the second ohmic metal layers which are longitudinally arranged, wherein the first Schottky metal layers tightly wrap peripheries of the second ohmic metal layers; when the irradiation-resistant GaN HEMT is in reverse conduction, the Schottky junction formed by the first gate region metal prevents diffusion of the source current towards the real gate of the irradiation-resistant GaN HEMT through the second ohmic metal layers along the p-type gallium nitride layer;
a direction from the source to the drain is a length direction, that is, an x direction, and a width direction is a y direction;
in the width direction, a minimum thickness of the first Schottky metal layers wrapping the peripheries of the second ohmic metal layers is a₀, a₀≥2 μm, and a ratio of an area of the second ohmic metal layers to that an area of the first Schottky metal layers is
$$\frac{1}{2} \sim 2$$
; and
the first gate region metal and the second gate region metal are in alternating arrangement in the width direction; a width of a single section of the first gate region metal is w₁, a width of a same section of the second gate region metal is w₂, a gap between the first gate region metal and the second gate region metal which are adjacent is d, wherein 10 μm≤w₁≤1000 μm, 10 μm≤w₂≤1000 μm, 2 μm≤d≤10 μm, and a ratio of area of the first gate region metal to that of the second gate region metal is
$$\frac{1}{2} \sim 2.$$

8. The irradiation-resistant GaN HEMT with decoupling reverse conduction capability according to claim 1, wherein a cross section of the second ohmic metal layers is a strip, circle, ellipse, or polygon shape.

9. The irradiation-resistant GaN HEMT with decoupling reverse conduction capability according to claim 1, wherein a direction from the source to the drain is a length direction, that is, an x direction, a length of the p-type gallium nitride layer is l₁, the first gate region metal and the second gate region metal are equal in a length l₂, and an overlapping length of the interconnection metal layer and the first gate region metal is l₃, wherein l₁≥l₂≥l₃.

10. A fabricating method of the irradiation-resistant GaN HEMT with decoupling reverse conduction capability according to claim 1, comprising the following steps:
1) enabling an epitaxial wafer to successively comprise the substrate layer, the gallium nitride layer, the barrier layer, and the p-type gallium nitride layer from bottom to top, and removing the p-type gallium nitride layer in a non-graphic region by using an inductively coupled plasma dry etching method, so that only the gate region retains the p-type gallium nitride layer;
2) enabling the dielectric layers to grow on the entire epitaxial wafer by using a plasma enhanced chemical vapor deposition method; in a source region and a drain region, etching the dielectric layers and the barrier layer and depositing first ohmic metal layers by using the inductively coupled plasma dry etching method and a photolithography stripping method; subsequently, at the first gate region metal, etching the dielectric layers and depositing the second ohmic metal layers; and at the first gate region metal and second gate region metal, etching the dielectric layers and depositing the Schottky metal layer;
3) enabling the dielectric layers to grow on the entire epitaxial wafer by using the plasma enhanced chemical vapor deposition method again; subsequently, removing the dielectric layers above the second gate region metal to form deposition holes by using the inductively coupled plasma dry etching method; and depositing the gate metal layers above the metal layer from which the dielectric layers are removed by using the photolithography stripping method;
4) removing the dielectric layers above the first gate region metal, the source and the drain to form deposition holes by using the inductively coupled plasma dry etching method; and depositing the interconnection metal layers above the metal layer from which the dielectric layers are removed by using the photolithography stripping method; and
5) finally, covering the entire epitaxial wafer with a passivation layer, and thickening the metal layer in bonding pad regions of the source, the drain, and a real gate of the irradiation-resistant GaN HEMT to complete preparation of the irradiation-resistant GaN HEMT.
